(19) United States
(12) Patent Application Publication
(10) Pub. No.: US 2023/0066599 A1
(43) Pub. Date: Mar. 2, 2023

(54) Method and Apparatus for Reconstructing the Position of Semiconductor Components on a Wafer

(71) Applicant: Robert Bosch GmbH, Stuttgart (DE)

(72) Inventors: Andreas Steimer, Schoemberg (DE); Eric Sebastian Schmidt, Heimsheim (DE); Mehul Bansal, Sindelfingen (DE); Stefan Patrick Lindt, Gerlingen (DE); Csaba Domokos, Simmozheim (DE); Matthias Werner, Stuttgart (DE); Michel Janus, Kirchentellinsfurt (DE)

(21) Appl. No.: 17/822,046

(22) Filed: Aug. 24, 2022

(30) Foreign Application Priority Data
Aug. 25, 2021 (DE) 10 2021 209 343.4

(51) Int. Cl. G06N 5/02

(52) U.S. Cl. CPC G06N 5/025

(57) ABSTRACT

A method determines an assignment rule in order to combine test results from different tests of the same semiconductor device. The method includes fitting a model, such as a linear regression model, using the model to predict the test data, calculating a cost matrix based on the predictions, and applying the Hungarian method to the cost matrix to obtain a new assignment rule and repeating these steps multiple times.

This application claims priority under 35 U.S.C. § 119 to patent application no. DE 10 2021 209 343.4, filed on Aug. 25, 2021 in Germany, the disclosure of which is incorporated herein by reference in its entirety.

The disclosure relates to a method for reconstructing the positions of semiconductor components on a wafer on which they were mounted, after which the semiconductor components were cut out of the wafer, and to an apparatus which is configured to carry out the method.

### BACKGROUND

In the packaging process of semiconductor components (in particular PowerMOS), the traceability of the semiconductor components to their original wafers and their original position on the wafer is lost. Specifically, this means that the position of each semiconductor component on a wafer is no longer retrievable once the wafer has been cut or diced (a method in which semiconductor components are separated from the wafer) and packaged. Packaging process providers are able to offer at least a rough matching between loose semiconductor components in final test (=testing process of the semiconductor components after packaging) and semiconductor components on the wafer in wafer-level tests (testing prior to packaging). However, this still leads to several thousand semiconductor components that cannot be assigned to multiple wafers. Since this is essentially a combinatorial problem, the complexity of the solution to the problem is factorial, since there are n factorial different ways in which to arrange the semiconductor components in the correct order, where n is the number of semiconductor components.

For ASIC semiconductor components a solution to this combinatorial problem exists. For this purpose, a unique identifier is stored in the memory of the ASIC semiconductor components during the wafer-level test, which enables the final test to be assigned to the wafer-level test after packaging. However, this is not possible for semiconductor components such as PowerMOS due to the absence of a memory.

### SUMMARY

The disclosure has the advantage that it enables a potential assignment to be determined between semiconductor components depending on results of the wafer-level test and packaged semiconductor components depending on the results of the final test, without requiring retrospectively added metadata, such as unique identifiers or similar.

The disclosure also has the advantage that it enables a one-to-one assignment between semiconductor components and their original position on the wafer, thus enabling better process control (e.g. root cause analysis of defective parts).

In a first aspect, the disclosure relates to a method, in particular a computer-implemented method, for determining an assignment rule which assigns variables from a first set of first variables to variables from a second set of second variables. The assignment rule can assign the first variables to the second variables in a one-to-one manner, i.e. each first variable is assigned a maximum of one second variable by the assignment rule, and preferably also vice versa. A set can be understood as a form of combination of the individual variables. Preferably, the first and second set are different sets that do not have a common variable. Preferably, an index is assigned to each of the variables of the first and second set. All indices of the first and second sets could be interpreted as index sets, thus as a set, the elements of which continuously index the variables of the first or second set. The assignment rule then assigns an index from the second index set to the first index set. The assignment rule therefore describes which first variable belongs to which second variable and preferably also vice versa. The assignment rule can be a list or table or similar.

The method begins by initializing the assignment rule and providing the first and second sets. The initial assignment rule can be chosen randomly or as an identity mapping. Other initial assignment rules are possible as alternatives, e.g. a predefined, already partially correct assignment.

This is followed by repeated execution of steps a)-d) as explained below. The repetitions can be carried out for a specified number of maximum repetitions, or an abort criterion can be defined, wherein the repetition is aborted if the abort criterion is met. For example, the abort criterion is a min. modification of the assignment rule.

a) Creating a dataset which contains the first variables and their respective second variables assigned according to the assignment rule. The data set can also be referred to as a training dataset, wherein the assigned second variables are so-called “labels” of the first variables. It should be noted that this step can be optional, since the subsequent steps that use this dataset essentially require only the information of the current assignment rule between the first and second variables, which can be provided either by the dataset or by a current assignment rule. The current assignment rule is the assignment rule that exists for the current repetition of steps a)-d), that is, the assignment rule that was used when creating the most recent version of the dataset.

b) Training a machine learning system in such a way that the machine learning system determines the assigned second variables of the data set as a function of the first variables. A training procedure can be understood to mean that parameters of the machine learning system are adjusted so that predictions of the machine learning system that are determined with it are as close as possible to the second variables (“labels”) of the dataset. The optimization can be carried out with respect to a cost function. The cost function preferably characterizes a mathematical difference between the outputs of the machine learning system and the labels. Optimization is preferably carried out using a gradient descent method. The machine learning system can be one or a plurality of decision trees, a neural network, a support vector machine, or similar. The training can be carried out until any further improvement of the machine learning system during the training is negligible, i.e. a second abort criterion is fulfilled.

c) Calculating a cost matrix, wherein entries in the cost matrix characterize a distance between the prediction of the machine learning system and the second variables according to the assignment rule, in particular between the predictions of the machine learning system and all variables of the second set. The distance can be determined with an L₂ norm. Other distance measures are also conceivable. The cost matrix can be structured in such a way that rows and columns are each assigned to a first variable, or to the prediction of the machine learning system depending on the first variable, and a second variable, wherein the entries characterize the distance between the respective assigned variables of the rows and columns. The entries that are not located on the diagonal of the cost matrix can be considered as transport costs, which must be expended to assign the first variables to the respective second variables of the corresponding rows/columns contrary to the assignment rule.

d) Optimizing the assignment rule depending on the cost matrix so that the assignment rule generates minimum total costs based on the cost matrix entries. The total cost is a sum of the cost matrix entries that are required to perform an assignment of the variables of the first set to the second set from the cost matrix according to the current assignment rule. In other words, the sum is optimized, in particular minimized, over the entries selected from the cost matrix according to the assignment rule. It should be noted that the entries are selected according to the assignment rule in such a way that the entries of the respective column and row of the cost matrix selected according to the assignment rule are those assigned to the first and second variables, which are assigned to each other according to the assignment rule.

The assignment rule determined in the last repetition of step d) is the final assignment rule, which is output in an optional step.

The variables can be scalars or vectors such as a time series, in particular acquired by a sensor, or indirectly determined sensor data. Preferably, the first and second variables are one or a plurality of measurement results from one measurement or from a plurality of different measurements, each of which was performed on one of a plurality of objects. In other words, each variable is assigned to one of the objects. In the step of creating the dataset, only a predeterminable number of measurement results of the plurality of measurement results may be used for the second variables. The assignment rule can specify which first and second variables are measurement results of the same object. Particularly preferably, the at least one measurement of the objects for the first variables was performed at one point in time and the measurement for the second variables at a second point in time, the second point in time being after the first point. The second point in time can be defined after the objects have been subjected to modification or alteration.

It is proposed that the assignment rule is optimized using a cost minimization algorithm over the given cost matrix. For example, an optimization is possible using the Hungarian method, which is applied to the cost matrix. The Hungarian method (also known as the Kuhn-Munkres algorithm) is an algorithm for solving weighted mapping problems. Alternatively, a greedy implementation of the cost minimization algorithm can be used.

It is also proposed that the machine learning system is a regression model, which determines the second variables as a function of the first variables and parameters of the regression model, wherein the parameters of the regression model are adjusted during the training.

Regression is used to model relationships between a dependent (often also the response variable) and one or more independent variables (often also called explanatory variables). Regression is capable of parameterizing a more complex function, so that this data is best represented according to a specific mathematical criterion. For example, the common method of least squares calculates a unique straight line (or hyperplane) that minimizes the sum of the squares of the deviations between the true data and this line (or hyperplane), i.e., the sum of the residual squares.

It is also proposed that the first and second variables characterize a product during its production according to different production process steps. For example, the second point in time here can be the time when a manufacturing process step has been completed. The product can be any product produced in a manufacturing facility. Preferably, when the product is manufactured the traceability to preceding process steps is lost (so-called “bulk material”), for example, if it is no longer possible to directly assign the product from the bulk material, e.g. screws, to a production batch. It is conceivable that the first variables characterize components, in particular parts, and the second variables characterize final products, wherein the assignment rule describes which component was processed to produce which product, or which component was installed in which product. An example of this is if the component in the product can no longer be removed non-destructively in order to read out a serial number. With the disclosure, it is then possible to assign the production batch of the component by means of measurements on the product.

The first and second variables can be measurement/test results or other properties of the products, components, etc. The first and second variables are usually slightly different to each other, e.g. due to manufacturing tolerances, but describe the same measurements/properties of the products, components, etc.

It is also proposed that the first variables are first test results or measurement results of semiconductor component elements on a wafer and the second variables are second test results or measurement results of the semiconductor component elements after they have been cut out of the wafer. Semiconductor component elements can be parts of electrical components that have been grown on the wafer, e.g. a transistor group of an integrated circuit. The test results can also relate to the entire semiconductor component. Linear regression has proved to be particularly effective in finding the best assignment rule for the machine learning system. This is based on a linear relationship, which in this case is a realistic assumption for the assignment of the test results. Linear regression is a special case of regression. In linear regression a linear function is assumed. It uses only relationships in which the dependent variable is a linear combination of the regression coefficients (but not necessarily of the independent variables).

It is also proposed that the first test results are wafer-level test results and the second test results are final test results. Preferably, there are fewer final test results than wafer-level test results. The tests are, e.g., voltage tests and/or contacting tests.

It is also proposed that the semiconductor components were produced on a plurality of different wafers. This is because it has been shown that the method is even able to find a correct assignment rule across a number of wafers within a reasonable computing time.

It is also proposed that the assignment rule is used to determine which second test result belongs to which first test result and it is then determined, depending on the associated first test result, at which position the semiconductor component was arranged within a wafer. This allows a reconstruction of positions, which for the first time makes it possible to uniquely trace the semiconductor components from the last production process steps of the semiconductor production to previous processing steps.

It is also proposed that in addition to the positions, further variables characterizing the wafer and/or the semiconductor components on the wafer and respectively assigned second test results are determined, wherein this data is combined into a further training data set, wherein a further machine learning system is trained depending on the training data set in order to predict the second test results.

The advantage of this is that the assignment can be used to create a further training dataset to train a further machine learning system to predict characteristics of a packaged semiconductor device at an early stage of the production process. This significantly reduces the time taken to detect deviations in the process parameters, in particular for parameters that can only be correctly evaluated during final tests (e.g. RDSon).

Another advantage obtained here is that the assignment can also be used to train a further machine learning system that actively identifies defective semiconductor chips. This saves process resources and reduces waste.

In other respects, the disclosure relates to an apparatus and a computer program, each of which is configured to carry out the above methods, and a machine-readable storage medium on which this computer program is stored.

### BRIEF DESCRIPTION OF THE DRAWINGS

In the following, exemplary embodiments are described in more detail by reference to the accompanying drawings. In the drawings:

FIG. 1 shows a schematic diagram of a packaging process;

FIG. 2 shows an exemplary embodiment of a flowchart of the disclosure; and

FIG. 3 shows a schematic diagram of a training apparatus.

### DETAILED DESCRIPTION

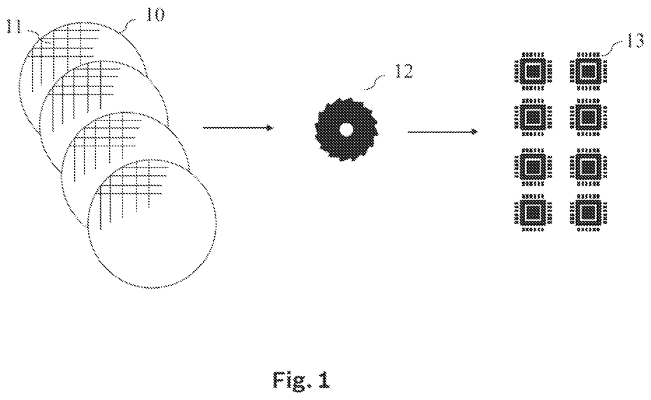

In the packaging process of semiconductor components or semiconductor devices, the traceability of the components to their original wafers and their original position on the wafer is lost. After the semiconductor component elements have been cut out, the individual semiconductor components can sometimes be mixed together, which means that without a unique marking of the components their position on the wafer is lost. This is shown schematically in FIG. 1. The wafers 10 each have a plurality of semiconductor components or semiconductor devices 11. At this stage, each semiconductor device 11 has a known position on the wafers 10. Typically, the semiconductor devices 11 are subjected to a plurality of tests at this stage, which are also known as wafer-level tests. The wafer 10 is then cut into parts so that the semiconductor devices 11 are separated from each other. The cutting can be carried out using a saw 12 or by laser. Finally, the cut-to-size semiconductor devices are packaged, e.g. installed in microcontrollers 13. This is then the latest stage in which the information as to the wafer 10 on which the semiconductor device was originally positioned, and at which position within the wafer 10, has been lost. Typically, the microcontrollers 13 with the semiconductor devices 11 are again subjected to a plurality of tests, also known as Final Test. However, since a mixing took place due to the cutting of the wafer 10 into parts, it is not easy to determine unambiguously on which wafer 10 a given semiconductor device 11 of the microcontroller 13 was arranged and which wafer-level test corresponds to which final test, i.e. which are the test results of the same semiconductor device. The semiconductor devices can be microelectronic modules, such as integrated circuits (hereafter also referred to as chips), sensors, etc.

One object of the disclosure is to restore the traceability following the packaging process in a semiconductor production process. Such an assignment enables further benefits, such as better process control or early predictions of final chip properties. In addition, the root cause analysis of the deviations measured at the chip level in the final test can be extended to the wafer production processes. This in turn enables a much deeper understanding of the processes and leads to better process control and hence to improved quality.

An assignment algorithm is proposed that consists of an alternating sequence of optimization of regression parameters (when regressing from wafer-level test to final-test data) followed by optimization of the assignment of test partners. The current assignment of the final test chips is used in each iteration as a ‘regression label’.

The disclosure also uses a cost-minimizing algorithm that can determine an optimal one-to-one assignment under a specified cost matrix. In order to construct a suitable cost matrix, a regression error is applied by calculating a suitable distance measure (e.g. L₂ norm) between the final test prediction of a trained regressor and the regression label. Based on this cost matrix, the algorithm rearranges the chips in the final test so as to minimize the regression loss. The regressor, or regression model, can be freely chosen depending on the characteristics of the data (e.g. linear regression for linear dependencies).

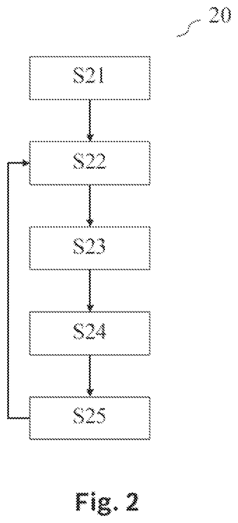

FIG. 2 shows a schematic flowchart 20 of a method for determining an assignment rule which maps the test results of the final test to the corresponding wafer-level test results. At the completion of the method, an assignment rule should be obtained that assigns the associated test results of the wafer-level test to the final tests. Thus, this rule describes the associated test results that originate from the same semiconductor component.

The method starts at step S21. This step initializes the assignment rule. The test results of the Wafer-Level Test (WLT) and Final Test (FT) are also provided in this step.

This is followed by step S22. In this step a training dataset is created that contains the WLT test results and their respective FT test results assigned according to the assignment rule.

After step S22 has completed, step S23 follows. In this step, a regressor f is trained such that the regressor determines the respectively assigned final tests according to the training data set, depending on the wafer-level tests (WLT):f(WLT)=FT. The regressor f can be a linear regression model. The regressor is trained in a known manner, e.g. by minimizing a regression error on the training data set by adjusting parameters of the regressor f.

Once the regressor has been trained, step S24 follows. A cost matrix is created in this step. The rows and columns are each assigned to a wafer-level test and final test. The entries in the cost matrix are determined from the training data by means of an L₂ norm between the regression prediction, depending on the corresponding WFT test result of the respective series and the corresponding FT test results of the respective column, and stored in the cost matrix.

After step S24 has completed, an optimization of the assignment rule follows in step S25. The optimization is performed by applying the Hungarian method to the cost matrix in order to obtain an improved assignment rule based on the cost matrix.

If an abort criterion is not met, steps S22 to S25 are executed again. The abort criterion can be a specified number of maximum repetitions.

If the abort criterion is met, the method is terminated and the assignment rule can be output.

In an optional step following step S25, the position of semiconductor components 11 on the wafer 10 is reconstructed using the assignment rule. The assignment rule can be used to determine the WLT test results in reverse, starting with the FT test results. Since the storage of the WLT test results usually additionally includes the position within the wafer where the respective test was performed, it is thus possible to reconstruct exactly where the corresponding semiconductor device was produced on the wafer.

It is conceivable that, depending on a position reconstruction after step S25, a control signal can be activated to control a physical system, such as a computer-controlled machine, such as a manufacturing machine, in particular processing machines for the wafers. For example, if the FT test results are not optimal, the control signal can adjust a previous production step accordingly to obtain better FT test results later.

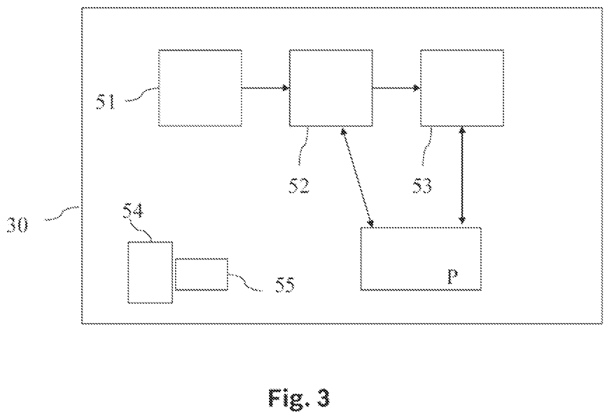

FIG. 3 shows a schematic diagram of an apparatus 30 for carrying out the method according to FIG. 2.

The apparatus comprises a provider 51 that provides the training dataset as described in step S22. The training data is then fed to the regressor 52, which uses this data to determine output variables. Output variables and training data are fed to an evaluator 53 which uses them to determine updated parameters of the regressor 52, which are transferred to the parameter memory P where they replace the current parameters. The evaluator 53 is configured to carry out step S23.

The steps performed by the apparatus 30 can be implemented as a computer program on a machine-readable storage medium 54 and executed by a processor 55.

The term “computer” covers any device for processing pre-definable calculation rules. These calculation rules can be provided in the form of software, or in the form of hardware, or in a mixed form of software and hardware.

What is claimed is:

1. A method for determining an assignment rule that assigns first variables from a first set of first variables to second variables from a second set of second variables, the method comprising:
initializing the assignment rule and providing the first set of first variables and the second set of second variables;
repeating the following:
training a machine learning system such that the machine learning system determines the second variables assigned according to the assignment rule as a function of the first variables;
calculating a cost matrix having cost matrix entries that characterize distances between predictions of the machine learning system as a function of the first variables and the second variables; and
optimizing the assignment rule based on the cost matrix so that the assignment of the first variables to the second variables according to the assignment rule generates minimum total costs based on the cost matrix entries.

2. The method according to claim 1, wherein the optimization of the assignment rule uses a Hungarian algorithm or a greedy implementation.

3. The method according to claim 2, wherein:
the cost matrix is square,
a largest value of the cost matrix entries is identified; and
when a number of the first variables and a number of the second variables does not match, empty entries of the cost matrix are filled with the largest value.

4. The method according claim 1, wherein the machine learning system is a regression model configured to determine the second variables as a function of the first variables and parameters of the regression model.

5. The method according to claim 1, wherein:
the first variables and the second variables characterize products during production of the products according to different production process steps, and
the assignment rule characterizes which of the first set of variables and the second set of variables characterize an identical product.

6. The method according to claim 1, wherein:
the first variables are first test results of semiconductor component elements on a wafer,
the second variables are second test results of the semiconductor component elements after they have been cut out from the wafer, and
the assignment rule characterizes which of the first test results and the second test results originate from the same semiconductor component element.

7. The method according to claim 6, wherein the first test results are wafer-level test results and the second test results are final test results.

8. The method according to claim 1, wherein the semiconductor component elements are produced on a plurality of different wafers.

9. The method according to claim 6, wherein:
the assignment rule is used to determine which second test result is associated with which first test result for each of the first test results and the second test results, and
the method determines, depending on the associated first test result, at which position the semiconductor component element was arranged within the wafer.

10. The method according to claim 9, wherein:
in addition to the positions, the method determines further variables characterizing the wafer and/or the semiconductor component elements on the wafer and respectively assigned second test results, and
the further variables are combined into a training data set, and a further machine learning system is trained depending on the training data set in order to predict the second test results.

11. The method according to claim 6, wherein the semiconductor component elements are power MOSFETs.

12. The method according to claim 1, wherein an apparatus is configured to carry out the method.

13. The method according to claim 1, wherein a computer program product comprises commands, which, during the execution of the computer program product by a computer, cause the computer to carry out the method.

14. The method according to claim 13, wherein the computer program product is stored on a non-transitory machine-readable storage medium.
